(19) United States
(12) Patent Application Publication
(10) Pub. No.: US 2026/0164791 A1
(43) Pub. Date: Jun. 11, 2026

(54) SEMICONDUCTOR STRUCTURE AND FABRICATION METHOD THEREOF

(71) Applicant: Vanguard International Semiconductor Corporation, Hsinchu (TW)

(72) Inventors: Chen-Dong Tzou, Taipei City (TW); Yun-Kai lai, Taichung City (TW); Tzu-Hsuan Chen, Hsinchu City (TW); Chih-Cherng Liao, Hsinchu City (TW); Chia-Hao Lee, Hsinchu County (TW)

(73) Assignee: Vanguard International Semiconductor Corporation, Hsinchu (TW)

(21) Appl. No.: 18/973,093

(22) Filed: Dec. 8, 2024

(51) Int. Cl. H10D 86/00; H01L 21/225; H01L 21/762

(52) U.S. Cl. CPC H10D 86/201; H10P 32/1406; H10P 32/171; H10P 90/1906; H10W 10/014; H10W 10/061; H10W 10/17; H10W 10/181

(57) ABSTRACT

A semiconductor structure includes a substrate, an isolation region, a patterned semiconductor layer, a patterned bonding layer and an epitaxial layer. The isolation region is buried in the substrate. The top surface of the isolation region and the top surface of the substrate are on the same plane. The patterned semiconductor layer is disposed directly above the isolation region. The patterned bonding layer is disposed between the isolation region and the patterned semiconductor layer. The epitaxial layer is disposed on the substrate and covers the patterned semiconductor layer.

### BACKGROUND OF THE INVENTION

### 1. Field of the Invention

The present disclosure relates generally to semiconductor technology, and more particularly to a semiconductor structure including a partial semiconductor-on-insulator region and a fabrication method thereof.

### 2. Description of the Prior Art

Bulk silicon substrates are typically used in integrated circuit manufacturing. In recent years, silicon-on-insulator (SOI) substrates have been developed. Compared with bulk silicon substrates, SOI substrates have many advantages, such as reduced parasitic capacitance, reduced leakage current, reduced latch up effect, etc. With the advancement of semiconductor technology, various components are integrated onto a single substrate. However, because the SOI substrates do not allow vertical current flow, some components such as complementary metal-oxide-semiconductor field-effect transistors (CMOSFETs), are suitable for SOI substrates, while others, such as dynamic random-access memory (DRAM) are not suitable for SOI substrates. Therefore, it is necessary to form a partial SOI region on a bulk substrate to facilitate the integration of various components. The main formation processes for SOI substrates include separation by implantation of oxygen (SIMOX) and smart-cut. However, forming a partial SOI region on a bulk substrate using SIMOX and smart-cut still presents numerous challenges that need to be overcome.

### SUMMARY OF THE INVENTION

In view of this, the present disclosure provides semiconductor structures and fabrication methods thereof. A buried isolation region is formed in a substrate, and a patterned semiconductor layer is formed directly above the buried isolation region, thereby fabricating a semiconductor structure including a partial semiconductor-on-insulator (partial SOI) region. The thickness of the buried isolation region is not limited by SIMOX process. Moreover, the buried isolation region can reduce the step height of an epitaxial layer grown on the substrate, thereby facilitating subsequent processes on the epitaxial layer.

According to an embodiment of the present disclosure, a semiconductor structure is provided and includes a substrate, an isolation region, a patterned semiconductor layer, a patterned bonding layer, and an epitaxial layer. The isolation region is buried in the substrate, and the top surface of the isolation region and the top surface of the substrate are on the same plane. The patterned semiconductor layer is disposed directly above the isolation region. The patterned bonding layer is disposed between the isolation region and the patterned semiconductor layer. The epitaxial layer is disposed on the substrate and covers the patterned semiconductor layer.

According to an embodiment of the present disclosure, a method of fabricating a semiconductor structure is provided and includes the following steps. A substrate is provided and an isolation region is formed in the substrate. The top surface of the isolation region and the top surface of the substrate are on the same plane. A donor substrate is provided and an ion implantation layer is formed within the donor substrate. The donor substrate is bonded to the substrate. A cleave is generated from the ion implantation layer to separate the donor substrate, and a semiconductor material layer is remained on the substrate. The semiconductor material layer is patterned to form a patterned semiconductor layer directly above the isolation region. In addition, an epitaxial layer is formed on the substrate to cover the patterned semiconductor layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a semiconductor structure according to an embodiment of the present disclosure.

FIG. 2 is a schematic cross-sectional view of a semiconductor structure according to another embodiment of the present disclosure.

FIG. 3 is a schematic cross-sectional view of a semiconductor structure according to further another embodiment of the present disclosure.

FIG. 4, FIG. 5, FIG. 6 and FIG. 7 are schematic cross-sectional views of some stages of a method of fabricating a semiconductor structure according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the semiconductor structure in use or operation in addition to the orientation depicted in the figures. For example, if the semiconductor structure in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

According to embodiments of the present disclosure, a buried isolation region is formed in a substrate by etching the substrate to form a trench and filling the trench with a dielectric material. A patterned semiconductor layer is formed directly above the isolation region by using smart-cut and etching processes. Thereafter, an epitaxial layer is grown on the entire substrate, thereby forming a semiconductor structure including a partial semiconductor-on-insulator (SOI) region.

In semiconductor structures of the present disclosure, the thickness of the buried isolation region is not limited by separation by implantation of oxygen (SIMOX) process. Therefore, the thickness of the isolation region may be increased according to the requirements of semiconductor devices, such as high-voltage operation conditions. Moreover, the buried isolation region can reduce the step height of an epitaxial layer on the substrate, thereby facilitating subsequent processes performed on the epitaxial layer, including photolithography, etching, and planarization processes. Accordingly, the accuracy of the photolithography process is improved, and the uniformities of the etching and the planarization processes in different areas of the substrate are also enhanced.

FIG. 1 is a schematic cross-sectional view of a semiconductor structure 100 according to an embodiment of the present disclosure. The semiconductor structure 100 includes a substrate 101 and an isolation region 103 buried in the substrate 101. Moreover, the top surface of the isolation region 103 and the top surface of the substrate 101 are on the same plane. In some embodiments, the substrate 101 may be composed of silicon (Si), silicon germanium (SiGe), silicon carbide (SiC), or other suitable semiconductor material. The isolation region 103 may be, for example, a shallow trench isolation (STI) structure, and may be composed of silicon oxide, silicon nitride, silicon oxynitride, a combination thereof, or other suitable dielectric material. The isolation region 103 has a first thickness T1, which is determined by the depth of a trench formed by etching the substrate 101. The first thickness T1 may be, for example, greater than about 0.2 micrometers (μm) and less than about 1 μm, such as about 0.4 μm, but not limited thereto. The first thickness T1 may be adjusted according to the requirements of semiconductor devices located on the partial SOI region of the substrate 101.

The semiconductor structure 100 further includes a patterned semiconductor layer 107 disposed directly above the isolation region 103, and a patterned bonding layer 105 disposed between the isolation region 103 and the patterned semiconductor layer 107. In some embodiments, the patterned semiconductor layer 107 may be composed of silicon (Si), silicon germanium (SiGe), silicon carbide (SiC), or other suitable semiconductor material. The patterned bonding layer 105 may be composed of silicon oxide. The patterned bonding layer 105 has a second thickness T2, and the patterned semiconductor layer 107 has a third thickness T3. The second thickness T2 is less than the third thickness T3, and the third thickness T3 is less than the first thickness T1 of the isolation region 103. In some embodiments, the second thickness T2 is, for example, about tens of angstroms (Å) to less than about 200 Å, and the third thickness T3 is, for example, about tens of nanometers (nm) to less than about 200 nm. In the vertical projection direction, for example, in the XY plane, the patterned semiconductor layer 107 is overlapped and aligned with the patterned bonding layer 105. In some embodiments, the vertical projection areas of the patterned semiconductor layer 107 and the patterned bonding layer 105 may be slightly extended beyond or aligned with the vertical projection area of the isolation region 103. In another embodiment, the vertical projection areas of the patterned semiconductor layer 107 and the patterned bonding layer 105 may be within the vertical projection area of the isolation region 103.

The semiconductor structure 100 further includes an epitaxial layer 109 (also referred to as a first epitaxial layer) disposed on substrate 101 and covering the patterned semiconductor layer 107 and the patterned bonding layer 105. In some embodiments, the epitaxial layer 109 may be composed of silicon (Si), silicon carbide (SiC), gallium nitride (GaN), gallium arsenide (GaAs), indium phosphide (InP), or other suitable semiconductor material. The epitaxial layer 109 includes a first portion 109-1 and a second portion 109-2. The first portion 109-1 is located directly above the isolation region 103, and the second portion 109-2 is located directly above the substrate 101 outside the isolation region 103. The first portion 109-1 and the second portion 109-2 are connected with each other to form the continuous epitaxial layer 109. Moreover, the first portion 109-1 of the epitaxial layer 109 may be in direct contact with the patterned semiconductor layer 107. In the vertical projection direction, for example, in the XY plane, the first portion 109-1 may be overlapped and aligned with the patterned semiconductor layer 107 and the patterned bonding layer 105. The second portion 109-2 of the epitaxial layer 109 may be in direct contact with the top surface of the substrate 101 and abuts both the side surface of the patterned semiconductor layer 107 and the side surface of the patterned bonding layer 105. In addition, as shown in FIG. 1, the bottom surface of the epitaxial layer 109 has a first height difference ΔH1 that is equal to the sum of the third thickness T3 of the patterned semiconductor layer 107 and the second thickness T2 of the patterned bonding layer 105. The top surface of the epitaxial layer 109 has a second height difference ΔH2 that is less than the first height difference ΔH1.

In some embodiments, the substrate 101 and the patterned semiconductor layer 107 have the same composition including a first semiconductor material, such as silicon (Si), silicon germanium (SiGe) or silicon carbide (SiC). The epitaxial layer 109 includes a second semiconductor material, such as gallium nitride (GaN), gallium arsenide (GaAs) or indium phosphide (InP). The first semiconductor material and the second semiconductor material may be different from each other. In other embodiments, the substrate 101, the patterned semiconductor layer 107 and the epitaxial layer 109 include the same semiconductor material, such as silicon (Si) or silicon carbide (SiC). In yet other embodiments, the substrate 101, the patterned semiconductor layer 107 and the epitaxial layer 109 include different semiconductor materials, where the substrate 101 may be composed of silicon (Si), the patterned semiconductor layer 107 may be composed of silicon germanium (SiGe) or silicon carbide (SiC), and the epitaxial layer 109 may be composed of gallium nitride (GaN), gallium arsenide (GaAs) or indium phosphide (InP). The aforementioned compositions of the substrate 101, the patterned semiconductor layer 107, and the epitaxial layer 109 are illustrated for example, but not limited thereto. The compositions of the substrate 101, the patterned semiconductor layer 107, and the epitaxial layer 109 may be determined based on the electrical and other requirements of various semiconductor devices integrated in the semiconductor structure 100.

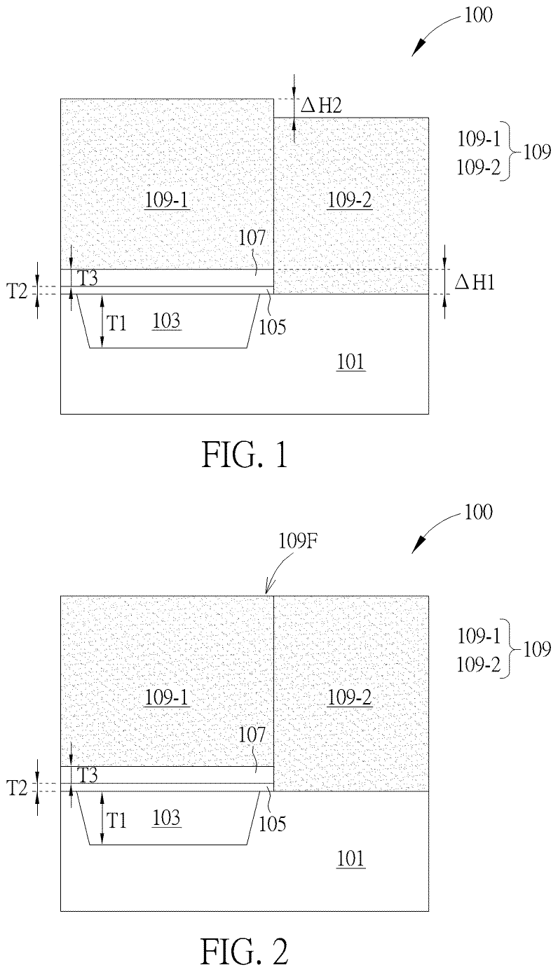

FIG. 2 is a schematic cross-sectional view of a semiconductor structure 100 according to another embodiment of the present disclosure. The bottom surface of the epitaxial layer 109 has a first height difference ΔH1 that is equal to the sum of the third thickness T3 of the patterned semiconductor layer 107 and the second thickness T2 of the patterned bonding layer 105, and the top surface of the epitaxial layer 109 is a planar surface 109F. In this embodiment, the epitaxial layer 109 is grown on the entire substrate 101 to cover the patterned semiconductor layer 107 and the patterned bonding layer 105. Thereafter, a planarization process such as chemical mechanical polish (CMP) process may be performed on the epitaxial layer 109 to form the planar surface 109F. The details of other features of the semiconductor structure 100 of FIG. 2 may refer to the aforementioned description of FIG. 1 and will not be repeated here.

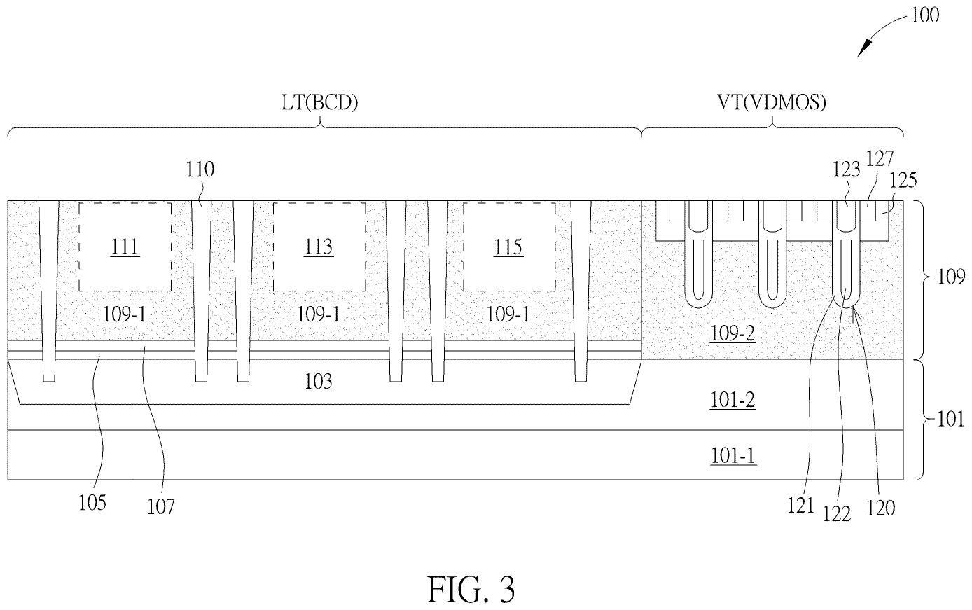

FIG. 3 is a schematic cross-sectional view of a semiconductor structure 100 according to further another embodiment of the present disclosure. In one embodiment, a lateral transistor LT, such as a bipolar junction transistor (BJT) 111, a complementary metal-oxide-semiconductor (CMOS) transistor 113, or a double-diffused metal-oxide-semiconductor (DMOS) transistor 115, is disposed in the first portion 109-1 of the epitaxial layer 109. In another embodiment, the lateral transistors LT include the bipolar junction transistor 111, the CMOS transistor 113 and the DMOS transistor 115 to constitute a Bipolar-CMOS-DMOS integrated structure (BCD) that is located in the partial SOI region of the semiconductor structure 100. In one embodiment, the bipolar junction transistor 111, the CMOS transistor 113 and the DMOS transistor 115 are each surrounded by deep trench isolation (DTI) structures 110 and isolated from each other. The deep trench isolation structures 110 may be extended downward from the top surface of the epitaxial layer 109, pass through the first portion 109-1, the patterned semiconductor layer 107 and the patterned bonded layer 105, until into the isolation region 103. As shown in FIG. 3, in the vertical projection direction, for example, in the XY plane, the boundaries of both the patterned semiconductor layer 107 and the patterned bonding layer 105 may be overlapped and aligned with the boundary of the isolation region 103, but not limited thereto. The boundaries of both the patterned semiconductor layer 107 and the patterned bonding layer 105 may be extended beyond the boundary of the isolation region 103 or be located inside the boundary of the isolation region 103. The deep trench isolation structures 110 may be filled with dielectric materials and/or conductive materials, such as silicon oxide and/or polysilicon.

In addition, a vertical transistor VT is disposed in the second portion 109-2 of the epitaxial layer 109. The vertical transistor VT may be, for example, a vertical double-diffused metal-oxide-semiconductor (VDMOS) transistor, an insulated gate bipolar transistor (IGBT) and/or a trench MOS transistor. As shown in FIG. 3, in one embodiment, the vertical transistor VT may be a vertical double-diffused metal-oxide-semiconductor transistor VDMOS, which includes a trench 120 formed in the second portion 109-2. A gate 123, a field plate 122 and a dielectric layer 121 are disposed in the trench 120. The gate 123 is located directly above the field plate 122. The dielectric layer 121 surrounds the gate 123 and the field plate 122 and separates the gate 123 from the field plate 122 vertically. A body region 125 is disposed in the second portion 109-2 and located on both sides of the trench 120. A source region 127 is disposed in the body region 125 and abuts the both sides of the trench 120. The body region 125 is, for example, a p-type well region, and the source region 127 is, for example, an n-type heavily doped region. In this embodiment, the substrate 101 may be constructed by an epitaxial layer 101-2 (also referred to as a second epitaxial layer) stacked on a base 101-1. The base 101-1 is, for example, an n-type heavily doped silicon substrate. The thickness of the base 101-1 is, for example, about 50 μm to about 750 μm. The epitaxial layer 101-2 is, for example, an n-type lightly doped silicon epitaxial layer. The thickness of the epitaxial layer 101-2 is, for example, about 3 μm to about 10 μm. The aforementioned description is illustrated for example, but not limited thereto.

The isolation region 103 is formed in the epitaxial layer 101-2 of the substrate 101, and a portion of the substrate 101, i.e., the heavily doped base 101-1, is used as the drain region of the vertical double-diffused metal-oxide-semiconductor transistor VDMOS. Since there is no isolation region 103 disposed directly below the second portion 109-2 of the epitaxial layer 109, the current of the transistor VDMOS can flow vertically between the base 101-1 (the drain region) and the source region 127. Furthermore, the current flowing laterally in the substrate 101 can be blocked by the isolation region 103 and will not flow to the Bipolar-CMOS-DMOS integrated structure BCD in the first portion 109-1. Moreover, as shown in FIG. 3, the epitaxial layer 109 may have a flat top surface, but not limited thereto. The second height difference ΔH2, as shown in FIG. 1, may also exist between the first portion 109-1 and the second portion 109-2 of the epitaxial layer 109 in other embodiment of FIG. 3. As the thickness of the epitaxial layer 109 is increased, the second height difference ΔH2 may be much smaller than the first height difference ΔH1. In one embodiment, the thickness of the isolation region 103 of the semiconductor structure 100 may be increased to greater than about 0.4 μm, and the step height between the bottom surfaces of the first portion 109-1 and the second portion 109-2 of the epitaxial layer 109 may be less than about 0.4 μm, for example, less than about 0.1 μm. Using the known method of forming a buried oxide region by smart cut and etching processes, an isolation region is not buried in a substrate. To ensure that the step height of an epitaxial layer is less than 0.1 μm, the thickness of the buried oxide region formed by the known method must be less than 0.1 μm. Compared with the buried oxide region formed by the known method, the embodiments of the present disclosure provide better design flexibility for the isolation region to adapt to the electrical requirements and operating conditions of various semiconductor devices.

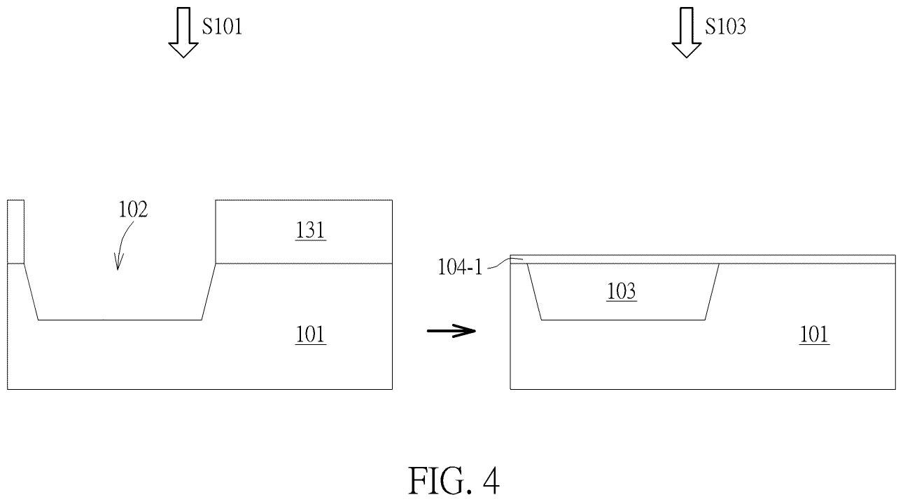

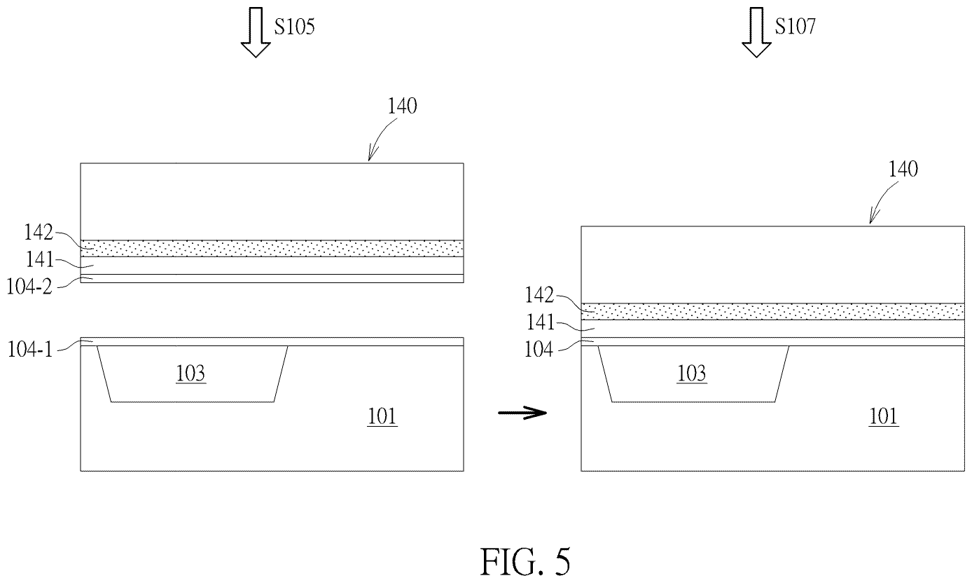

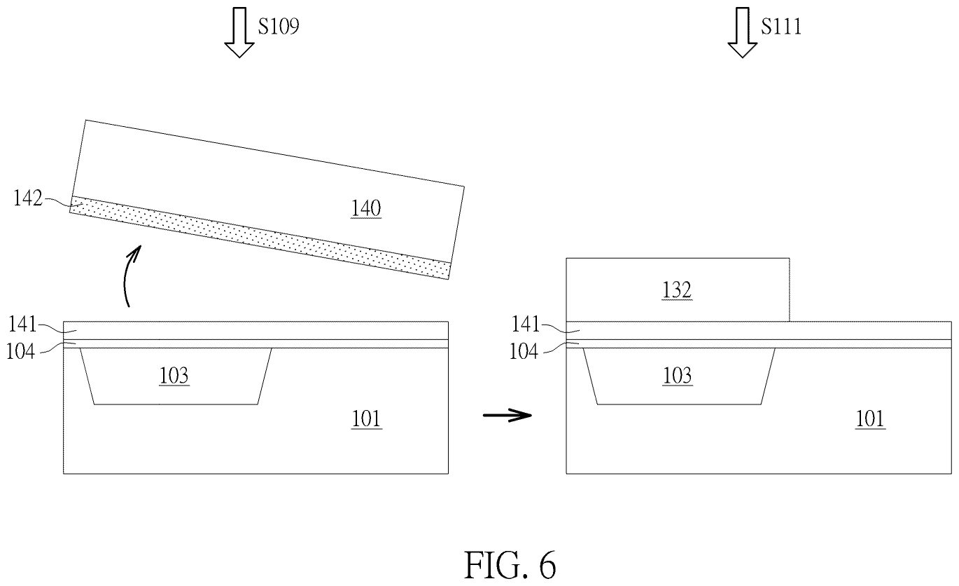

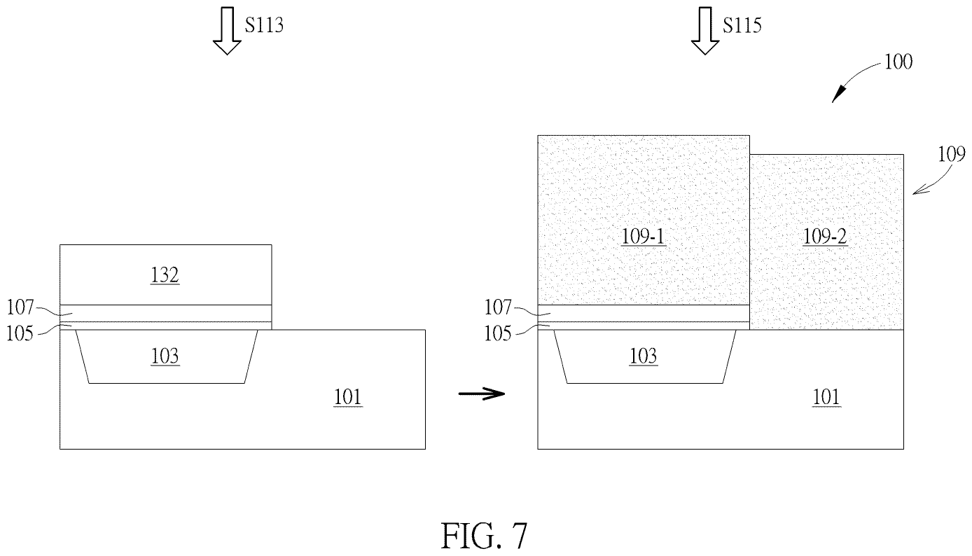

FIG. 4, FIG. 5, FIG. 6 and FIG. 7 are schematic cross-sectional views of some stages of a method of fabricating a semiconductor structure 100 according to an embodiment of the present disclosure. Referring to FIG. 4, in step S101, a substrate 101 is provided, and a patterned hard mask 131 is formed on the substrate 101. The patterned hard mask 131 has an opening to expose an area of the substrate 101 and the area is a predetermined region for forming lateral transistors, such as a Bipolar-CMOS-DMOS integrated structure or other semiconductor devices suitable for a SOI substrate. Then, a trench 102 is formed in the substrate 101 by an etching process through the opening of the patterned hard mask 131. Still referring to FIG. 4, in step S103, the patterned hard mask 131 is removed, and the trench 102 is filled with a dielectric material such as silicon oxide. Then, a chemical mechanical planarization (CMP) process is performed on the substrate 101 to form an isolation region 103, for example, a shallow trench isolation (STI) structure. The isolation region 103 is buried in the substrate 101, and the top surface of the isolation region 103 and the top surface of the substrate 101 are on the same plane. Thereafter, a first bonding layer 104-1 is formed on the surface of the substrate 101 to cover the isolation region 103 by a deposition process. In one embodiment, the composition of the first bonding layer 104-1 is, for example, silicon oxide, and the thickness of the first bonding layer 104-1 is, for example, less than about 100 Å.

Next, referring to FIG. 5, in step S105, a donor substrate 140 such as a silicon substrate is provided. In one embodiment, a second bonding layer 104-2 such as a silicon oxide layer is optionally formed on the surface of the donor substrate 140 facing the substrate 101 by thermal oxidation process. The thickness of the second bonding layer 104-2 is, for example, less than 100 Å. Then, an ion implantation process is used to implant hydrogen (H) ions or helium (He) ions into the donor substrate 140, thereby forming an ion implantation layer 142. A portion of the donor substrate 140 (hereinafter referred to as a semiconductor material layer 141) is located between the ion implantation layer 142 and the second bonding layer 104-2. The thickness of the semiconductor material layer 141 is controlled by the implantation depth of the ion implantation process for forming the ion implantation layer 142. For example, the thickness of the semiconductor material layer 141 may be controlled by adjusting the implantation energy of the ion implantation process. When the implanted energy is set lower, the thickness of the semiconductor material layer 141 is thinner. Still referring to FIG. 5, in step S107, the donor substrate 140 is bonded to the substrate 101 through the first bonding layer 104-1 and the second bonding layer 104-2. After the bonding process, the first bonding layer 104-1 and the second bonding layer 104-2 constitute a bonding layer 104, and the thickness of the bonding layer 104 is, for example, less than about 200 Å.

In another embodiment, in step S105, the second bonding layer 104-2 may be optionally not formed on the surface of the donor substrate 140 facing the substrate 101. In step S107, the donor substrate 140 is bonded to the substrate 101 through the first bonding layer 104-1 (or referred to as the bonding layer 104). In this embodiment, the thickness of the bonding layer 104 is, for example, less than about 100 Å.

Next, referring to FIG. 6, in step S109, a smart-cut process is used to generate a cleavage from the ion implantation layer 142 to separate the donor substrate 140, thereby leaving the semiconductor material layer 141 on substrate 101. The semiconductor material layer 141 and the bonding layer 104 are disposed on the entire substrate 101 to cover the isolation region 103. Still referring to FIG. 6, in step S111, a patterned hard mask 132 is formed on the semiconductor material layer 141 by deposition and patterning processes. The patterned hard mask 132 is located in a partial SOI region where lateral transistors, such as a Bipolar-CMOS-DMOS integrated structure or other semiconductor devices suitable for a SOI substrate, are to be formed, and a portion of the semiconductor material layer 141 is exposed.

Then, referring to FIG. 7, in step S113, the semiconductor material layer 141 and the bonding layer 104 are simultaneously patterned by an etching process and utilizing the patterned hard mask 132 as an etch mask, thereby forming a patterned semiconductor layer 107 and a patterned bonding layer 105, both are located directly above the isolation region 103. The patterned bonding layer 105 is located between the patterned semiconductor layer 107 and the isolation region 103. In the vertical projection direction, the patterned semiconductor layer 107 and the patterned bonding layer 105 are overlapped and aligned with each other. Furthermore, by using the patterned hard mask 132, the formation area of both the patterned semiconductor layer 107 and the patterned bonding layer 105 can be controlled, thereby adjusting the positional relationship between the boundaries of both the patterned semiconductor layer 107 and the patterned bonding layer 105 and the boundary of the isolation region 103.

Still referring to FIG. 7, in step S115, the patterned hard mask 132 is removed. Then, an epitaxial layer 109 is formed on the entire substrate 101 by an epitaxial growth process to cover the patterned semiconductor layer 107 and the patterned bonding layer 105, thereby forming the semiconductor structure 100. The epitaxial layer 109 includes a first portion 109-1 grown directly above the isolation region 103, and a second portion 109-2 grown directly above the substrate 101 outside the isolation region 103. Moreover, the bottom surface of the first portion 109-1 is higher than the bottom surface of the second portion 109-2. The height difference between the bottom surfaces of the first portion 109-1 and the second portion 109-2 is equal to the sum of the thickness of the patterned semiconductor layer 107 and the thickness of the patterned bonding layer 105. In addition, there is a height difference between the top surfaces of the first portion 109-1 and the second portion 109-2, which is less than the height difference between their bottom surfaces. This height difference between the top surfaces of the first portion 109-1 and the second portion 109-2 is decreased as the thickness of the epitaxial layer 109 is increased. Thereafter, a planarization process may be performed on the epitaxial layer 109 to produce a flat top surface.

Subsequently, multiple integrated circuit fabrication processes, including photolithography, ion implantation, deposition, and etching processes, may be performed on the epitaxial layer 109, thereby integrating various semiconductor devices into a monolithic substrate. Referring to FIG. 3, in one embodiment, lateral transistors, for example, Bipolar-CMOS-DMOS (BCD) integrated structure, are formed in the first portion 109-1 of the epitaxial layer 109 and located in the partial SOI region, and a vertical transistor, for example, a vertical double-diffused metal-oxide-semiconductor (VDMOS) transistor, is formed in the second portion 109-2 of the epitaxial layer 109 and located in the non-SOI region.

According to the embodiments of the present disclosure, the partial SOI region is formed in a monolithic substrate through the isolation region buried in the substrate, thereby enhancing the voltage rating of semiconductor devices in the partial SOI region, and the non-SOI region can accommodate semiconductor devices requiring vertical current flow. Therefore, the semiconductor structures of the present disclosure can integrate a Bipolar-CMOS-DMOS structure and a vertical double-diffused metal-oxide-semiconductor transistor into a single chip.

In addition, according to the embodiments of the present disclosure, since the isolation region is buried in the substrate, the thickness of the isolation region does not affect the height difference of different portions of the epitaxial layer, thereby significantly reducing the step height of the epitaxial layer. This facilitates subsequent multi-step processes on the epitaxial layer, such as improving the accuracy of photolithography process and enhancing the uniformities of polishing and etching processes.

Furthermore, compared with a buried oxide region formed by the SIMOX process, the thickness of the isolation region in the semiconductor structures of the present disclosure is not limited by the oxygen implantation depth, oxygen implantation thickness, and interface stress issue of the buried oxide region in the SIMOX process. Therefore, the isolation region in the embodiments of the present disclosure has better design flexibility to adapt to the electrical requirements and the operating conditions of various semiconductor devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate;
an isolation region, buried in the substrate, wherein a top surface of the isolation region and a top surface of the substrate are on the same plane;
a patterned semiconductor layer, disposed directly above the isolation region;
a patterned bonding layer, disposed between the isolation region and the patterned semiconductor layer; and
a first epitaxial layer, disposed on the substrate and covering the patterned semiconductor layer.

2. The semiconductor structure of claim 1, wherein the substrate comprises a second epitaxial layer, and the isolation region is buried in the second epitaxial layer.

3. The semiconductor structure of claim 1, wherein a bottom surface of the first epitaxial layer has a first height difference, a top surface of the first epitaxial layer has a second height difference, and the second height difference is smaller than the first height difference, or the first epitaxial layer has a flat top surface.

4. The semiconductor structure of claim 1, wherein the isolation region comprises a shallow trench isolation structure, and a composition of the isolation region comprises silicon oxide.

5. The semiconductor structure of claim 1, wherein in a vertical projection direction, the patterned semiconductor layer and the patterned bonding layer are overlapped and aligned with each other.

6. The semiconductor structure of claim 1, wherein a composition of the patterned bonding layer comprises silicon oxide, and a thickness of the patterned bonding layer is less than a thickness of the patterned semiconductor layer.

7. The semiconductor structure of claim 1, wherein the substrate and the patterned semiconductor layer have the same composition comprising a first semiconductor material, and the first epitaxial layer comprises a second semiconductor material that is different from the first semiconductor material.

8. The semiconductor structure of claim 1, wherein the substrate, the patterned semiconductor layer, and the first epitaxial layer comprise semiconductor materials different from each other, or all the substrate, the patterned semiconductor layer, and the first epitaxial layer comprise the same semiconductor material.

9. The semiconductor structure of claim 1, wherein the first epitaxial layer comprises a first portion directly above the isolation region, and a second portion directly above the substrate outside the isolation region.

10. The semiconductor structure of claim 9, further comprises:
a lateral transistor, disposed in the first portion of the first epitaxial layer; and
a vertical transistor, disposed in the second portion of the first epitaxial layer.

11. The semiconductor structure of claim 9, wherein the second portion of the first epitaxial layer abuts a side surface of the patterned semiconductor layer and a side surface of the patterned bonding layer.

12. A method of fabricating a semiconductor structure, comprising:
providing a substrate;
forming an isolation region in the substrate, wherein a top surface of the isolation region and a top surface of the substrate are on the same plane;
providing a donor substrate with an ion implantation layer formed in the donor substrate;
bonding the donor substrate to the substrate;
generating a cleavage from the ion implantation layer to separate the donor substrate and leave a semiconductor material layer on the substrate;
patterning the semiconductor material layer to form a patterned semiconductor layer directly above the isolation region; and
forming an epitaxial layer on the substrate to cover the patterned semiconductor layer.

13. The method of claim 12, further comprising:
forming a bonding layer on a surface of the substrate to bond the donor substrate to the substrate after the isolation region is formed,
wherein the bonding layer is simultaneously patterned with patterning the semiconductor material layer to form a patterned bonding layer located between the isolation region and the patterned semiconductor layer.

14. The method of claim 13, wherein a bottom surface of the epitaxial layer has a first height difference that is equal to the sum of a thickness of the patterned semiconductor layer and a thickness of the patterned bonding layer.

15. The method of claim 14, wherein a top surface of the epitaxial layer has a second height difference that is smaller than the first height difference, or the epitaxial layer has a flat top surface.

16. The method of claim 12, further comprising:
forming a first bonding layer on a surface of the substrate after the isolation region is formed; and
forming a second bonding layer on a surface of the donor substrate before forming the ion implantation layer,
wherein the first bonding layer and the second bonding layer constitute a bonding layer to bond the donor substrate to the substrate, and the bonding layer is simultaneously patterned with patterning the semiconductor material layer to form a patterned bonding layer located between the isolation region and the patterned semiconductor layer.

17. The method of claim 12, wherein forming the isolation region comprises:
etching the substrate to form a trench;
filling the trench with a dielectric material; and
performing a planarization process on the substrate to form the isolation region, wherein the isolation region comprises a shallow trench isolation structure.

18. The method of claim 12, wherein forming the ion implantation layer comprises implanting hydrogen ions or helium ions into the donor substrate by an ion implantation process, and a thickness of the semiconductor material layer is controlled by an implantation depth of the ion implantation process.

19. The method of claim 12, wherein the epitaxial layer comprises a first portion grown directly above the isolation region, and a second portion grown directly above the substrate outside the isolation region.

20. The method of claim 19, further comprising:
forming a lateral transistor in the first portion of the epitaxial layer; and
forming a vertical transistor in the second portion of the epitaxial layer.
